(19) United States
(12) Patent Application Publication
(10) Pub. No.: US 2012/0211050 A1
(43) Pub. Date: Aug. 23, 2012

(54) SOLAR BATTERY MODULE

(75) Inventor: Yoichiro Nishimoto, Tokyo (JP)

(73) Assignee: Mitsubishi Electric Corporation, Tokyo (JP)

(21) Appl. No.: 13/505,237

(22) PCT Filed: Dec. 25, 2009
(86) PCT No.: PCT/JP2009/071689

§ 371 Date: Apr. 30, 2012

(51) Int. Cl. H01L 31/05

(52) U.S. Cl. 136/244

(57) ABSTRACT

Connection tabs include: a first connection tab 72 that is electrically connected to a connection electrode 62 on a rear side of the first solar battery cell 11 and extends to a rear side of the second solar battery cell 21; and a second connection tab 71 that is electrically connected to a connection electrode 52 on a light-receiving side of the second solar battery cell 21 and has a bent folded-back portion which extends to the rear side of the second solar battery cell 21 near the first solar battery cell 11 from the second solar battery cell. The first connection tab 71 and the second connection tab 72 are connected in a connection region that is within an overlapping region in which the first connection tab 72 and the second connection tab 21 overlap in a rear side of the second solar battery cell 21, and that is narrower than the overlapping region in the first direction.

### FIELD

The present invention relates to a solar battery module.

### BACKGROUND

The power generation costs of solar power generation are still high, and thus to spread solar power generation it is necessary to reduce the power generation costs even further. Methods for reducing power generation costs can roughly be broken down into three areas: “improving photoelectric conversion efficiency,” “reducing material costs and production costs,” and “improving solar battery module reliability.”

Although there are various techniques for improving the photoelectric conversion efficiency of a solar battery, most of the currently used crystalline type silicon (Si) solar batteries adopt a technique in which a high-concentration diffusion layer of the same conductivity type as the used substrate is provided on a rear side and carrier recombination in the rear side is restrained by the internal electric field involved by the obtained junction. This structure is called a back surface field (BSF) structure, and the rear side diffusion layer is called a BSF layer. Generally, the BSF layer is formed using a p-type wafer and diffusing aluminum (Al) by printing and baking an Al paste on the rear side.

Next, looking at solar batteries from a material cost perspective, the substrate (wafer) takes most of the costs. Recently, due to the short supply of a silicon (Si) raw material for solar batteries, a wafer price has increased sharply. For this reason or the like, solar battery manufacturers have dealt with this problem by using thinner wafers. However, the above-described formation of the above-described BSF layer using an Al paste is a factor which is hindering wafers from being thinned. This is because cell warp increases as the wafer becomes thinner, due to a difference in the thermal expansion coefficient of

Al and Si during baking, thereby causing the problem that fracturing occurs when the cell is modularized.

Consequently, currently, the development of technique to change for the passivation on the rear side from the BSF layer to an insulating film is progressing. It is thus thought that main future solar batteries will have their rear sides that are passivated with an insulating film. Although the rear side electrode in this type of solar battery may be a of point-contact type in which the electrode connected to the rear side of the wafer at points, or of a comb type electrode in which the electrode is provided on the rear side of the wafer in a comb shape, it is thought that the comb type electrodes will enter the mainstream for the reason of their high productivity.

Finally, power generation costs will be described from a perspective of reliability of a solar battery module. Supposing, for example, that a solar battery module output is constant, if the life of a solar battery module can be extended from 10 years to 20 years, then power generation costs will be halved. Thus, power generation costs can be reduced also by improving the long-term reliability of the solar battery modules.

A solar battery other than an integrated thin-film solar battery, as represented by an amorphous silicon (a-Si) solar battery, is modularized by interconnecting the individual solar battery cells after the production of the solar battery cells is completed. Since a voltage of one solar battery cell is as small as about 0.5 V to 1.0 V, a plurality of solar battery cells are connected in series by a flat plate conductive wire called a tab (or a ribbon) or with metal foil called an interconnector to obtain a high voltage.

Although a tab is used for terrestrial solar batteries because a current per solar battery cell is large, the stress applied on the tab has a large effect on the long-term reliability of the solar battery modules. Specifically, since the solar battery modules are placed outside, the temperature of the solar battery modules cyclically changes, so that the tabs repeatedly expand and contract. Consequently, the tabs undergo metal fatigue, and ultimately they fracture. Therefore, alleviating tab stress is effective in improving the long-term reliability of solar battery modules.

In response, a technique in which allowance is provided based on a devised manner in a connecting location between the solar battery cell and the tab (for example, see Patent Literature 1), a technique in which a uniquely-shaped interconnector is employed (for example, see Patent Literature 2), and a technique in which a three-dimensionally bent interconnector is employed (for example, see Patent Literature 3) have been proposed.

### CITATION LIST

### Patent Literature

Patent Literature 1: Japanese Translation of PCT International Application No. 2009-518828

Patent Literature 2: Japanese Patent Application Laid-open No. H6-196744

Patent Literature 3: Japanese Patent Application Laid-open No. 2008-227085

### SUMMARY

### Technical Problem

However, in the technique described in Patent Literature 1, since the path through which the current flows is greatly extended, the resistance loss over the whole module increases. Increase in resistance loss can cause decrease in a fill factor (FF) of the module, and as a result, there is caused a problem of decreasing conversion efficiency of the module.

Further, in Patent Literature 2 and Patent Literature 3 the cells are connected using an interconnector. However, terrestrial solar batteries have a large extraction current, and so when an interconnector is used, the resistance increases and resistance loss increases. Consequently, from the perspective of solar battery properties, application of an interconnector to the terrestrial solar batteries is difficult.

On the other hand, an idea in Patent Literature 3 in which the interconnector is three-dimensionally bent between the cells is not difficult to apply to the tab. Accordingly, suppose that connection is made with three-dimensionally bending the tab in between cells. In this case, it is thought that a problem will arise in the connection between the tabs. Specifically, if trying to make connection with bending the tab in the condition of the tab being coated with solder, then the bent portion of the tab can be itself connected by the heat of the soldering, so that the desired structure is not easily produced. When trying to produce the desired structure, a method of connecting the tabs to each other by sandwiching the bent portion of the tab with an unsolderable material so that the bent portion is not connected, or a method of bending the tabs after they have been connected to each other, has to be employed, for example. However, these methods suffer from problems of productivity as the methods involve an amount of time and effort, and are thus not practical. Consequently, it is thought that the technique described in Patent Literature 3 would be difficult to apply to the terrestrial solar batteries.

The present invention has been achieved in view of the above-described circumstances, and it is an object of the present invention to provide a solar battery module having excellent long-term reliability and power generation costs.

### Solution to Problem

In order to solve the above-mentioned problems and achieve the objection, the present invention provides a solar battery module having a first solar battery cell and a second solar battery cell, respective in-plane directions of which are substantially identical, and which are adjacent to each other in a first direction, the cells each having connection electrodes on a light-receiving side and a rear side, the first solar battery cell and the second solar battery cell being electrically connected in series by connection tabs formed from an electrically conductive material, wherein the connection tabs include: a first connection tab that is electrically connected to the connection electrode on the rear side of the first solar battery cell and extends to the rear side of the second solar battery cell; and a second connection tab that is electrically connected to the connection electrode on the light-receiving side of the second solar battery cell and has a bent folded-back portion which extends to the rear side of the second solar battery cell near the first solar battery cell from the second solar battery cell, wherein the first connection tab and the second connection tab are connected in a connection region that is within an overlapping region in which the first connection tab and the second connection tab overlap in a rear side of the second solar battery cell, and that is narrower than the overlapping region in the first direction.

### Advantageous Effects of Invention

The present invention provides the advantageous effects that allowance of the connection tab is increased, so that the stress on the connection tabs caused by cyclical changes in the module temperature is alleviated, and fracturing of the connection tabs due to thermal stress can be prevented, thereby making it possible to improve long-term reliability and reduce power generation costs.

### BRIEF DESCRIPTION OF DRAWINGS

FIG. 1 is a schematic diagram illustrating an outline of the configuration of a solar battery module according to an embodiment of the present invention.

FIG. 2 is a schematic diagram illustrating an enlarged view of a connection portion of a solar battery cell constituting the solar battery module according to the embodiment of the present invention, in which a connection portion in FIG. 1 is magnified and illustrated.

FIG. 3-1 is a plan view of a solar battery cell on a light-receiving face side, the cell constituting the solar battery module according to the embodiment of the present invention.

FIG. 3-2 is a plan view of a solar battery cell on the opposite side (back side) of the light-receiving side, the cell constituting the solar battery module according to the embodiment of the present invention.

FIG. 3-3 is a main parts cross-sectional view illustrating a configuration of a solar battery cell according to the embodiment of the present invention.

FIG. 4 is a schematic diagram illustrating the case where a connection portion is provided over the entire area of a folded-back portion of a connection tab on the rear side of a solar battery cell.

FIG. 5 is a schematic diagram illustrating a method for connecting conventional solar battery modules, in which the solar battery modules are interconnected by one connection tab.

FIG. 6 is a schematic diagram illustrating the case where connection tabs are connected by three-dimensionally bending a connection tab between solar battery cells.

FIG. 7-1 is a plan view of main parts illustrating an example of a rear side electrode pattern of the solar battery module according to the present embodiment.

FIG. 7-2 is a cross-sectional view of the main parts illustrating an example of a rear side electrode pattern of the solar battery module according to the present embodiment.

### DESCRIPTION OF EMBODIMENTS

Embodiments of solar battery modules according to the present invention will now be described in more detail with reference to the drawings. It is noted that the present invention is not limited to the following description, and may be appropriately changed without departing from the scope of the invention. Further, for easy understanding, the scale of the various parts in the drawing may be inaccurate with respect to the actual ones. The same also applies to parts among the drawings.

### Embodiment

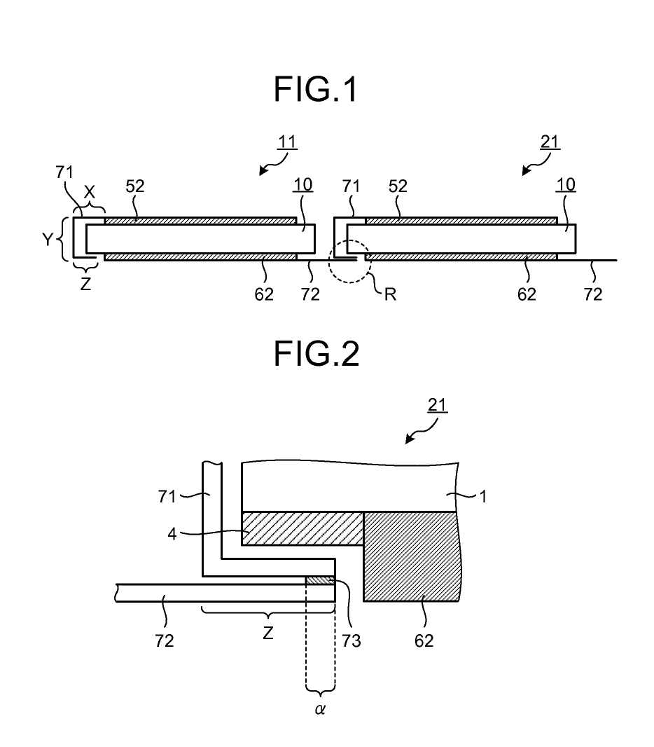

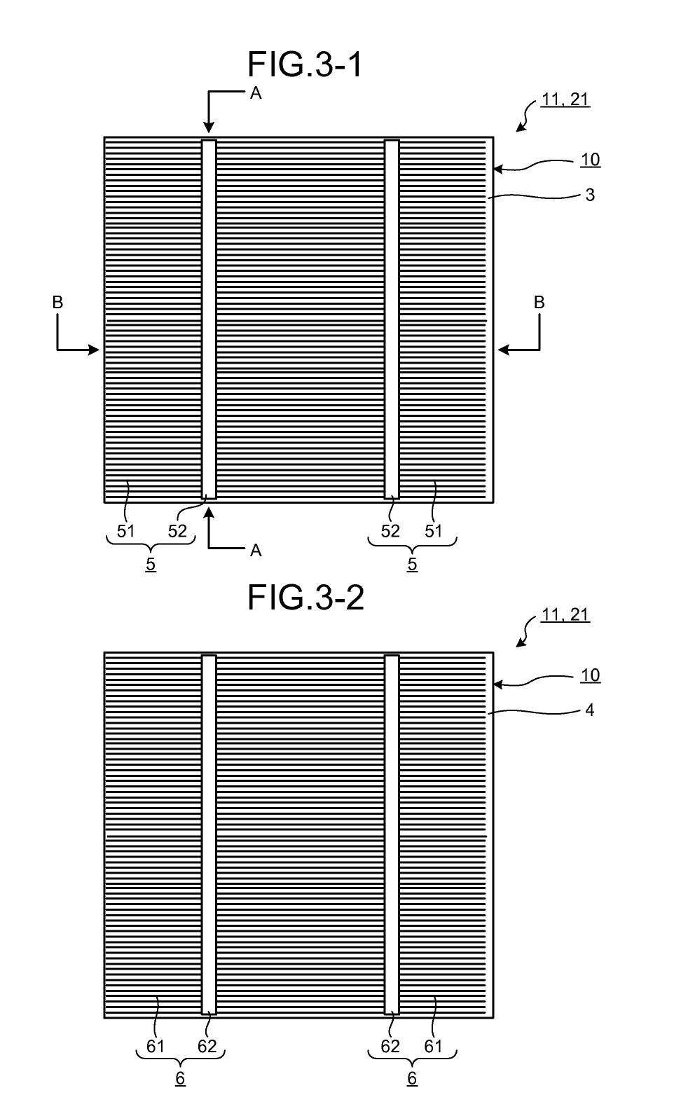

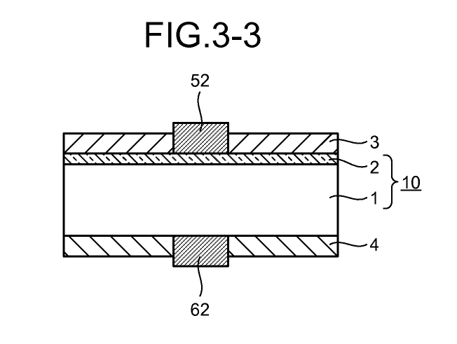

FIG. 1 is a schematic diagram illustrating an outline of the configuration of a solar battery module according to the embodiment of the present invention. FIG. 2 is a schematic diagram illustrating an enlarged view of a connection portion of solar battery cells 11 and 21 constituting the solar battery module according to the embodiment of the present invention, in which a connection portion R in FIG. 1 is magnified and illustrated. FIG. 3-1 is a plan view of solar battery cells 11 and 21 on a light-receiving side, constituting the solar battery module according to the embodiment of the present invention. FIG. 3-2 is a plan view of the solar battery cells 11 and 21 on a side (back side) opposite to the light-receiving side, constituting the solar battery module according to the embodiment of the present invention. FIG. 3-3 is a cross-sectional view of main parts illustrating a configuration of the solar battery cells 11 and 21 according to the embodiment of the present invention. Note that FIG. 1 corresponds to a cross-section taken along a line segment A-A in FIG. 3-1, and FIG. 3-3 corresponds to a cross-section taken along a line segment B-B in FIG. 3-1.

In the solar battery cells 11 and 21 according to the present embodiment, an anti-reflection film 3 formed from a silicon nitride film is formed on a light-receiving side of a semiconductor substrate 10 which is a solar battery substrate having a photoelectric conversion function and has a p-n junction. The semiconductor substrate 10 has an impurity diffusion layer (n-type impurity diffusion layer) 2 formed by phosphorus diffusion on a light-receiving side of a semiconductor substrate 1 that is formed from p-type silicon, for example.

As the semiconductor substrate 1, a p-type monocrystalline or polycrystalline silicon substrate may be used. However, the substrate is not limited to this, and an n-type silicon substrate may be used. Further, a silicon oxide film may be used for the anti-reflection film 3. In addition, tiny bumps may be formed as a textured structure on a surface of the light-receiving side of the semiconductor substrate 1 of the solar battery cell. These tiny bumps act as a structure that increases an area for absorbing the external light on the light-receiving side and reduces a reflectance of the light-receiving side surface so as to trap light there.

On the light-receiving side of the semiconductor substrate 1, a comb-shaped light-receiving side electrode 5 formed from an electrode material including silver and glass penetrates through the anti-reflection film 3 and is electrically connected to the impurity diffusion layer (n-type impurity diffusion layer) 2. As the light-receiving side electrode 5, a plurality of long, thin light-receiving side grid electrodes 51 are aligned in an in-plane direction of the light-receiving side surface of the semiconductor substrate 1. Light-receiving side bus electrodes 52 electrically-conducted to the light-receiving side grid electrodes 51 are provided to be substantially orthogonal to the light-receiving side grid electrodes 51 in an in-plane direction of the light-receiving side surface of the semiconductor substrate 1, and each electrically connected to the impurity diffusion layer 2 at bottom portions thereof.

On the other hand, on the rear side (face on the opposite side of the light-receiving side) of the semiconductor substrate 10, a rear face insulating film 4, that is an insulating film over the entire, is provided. By providing the rear side insulating film 4 on the rear side of the semiconductor substrate 10, defects on the rear side of the silicon substrate can be inactivated. For the rear side insulating film 4, a silicon nitride film or a silicon oxide film is used.

On the rear side (face on the opposite side of the light-receiving side) of the semiconductor substrate 10, a comb-shaped rear side electrode 6 formed from an electrode material that includes silver and glass, for example a silver (Ag)—aluminum (Al) based alloy, penetrates through the rear side insulating film 4 and is electrically connected to the semiconductor substrate 1. As the rear side electrode 6, a plurality of long, thin rear side grid electrodes 61 are provided aligned in an in-plane direction of the rear surface of the semiconductor substrate 1. Rear side bus electrodes 62 electrically conducted to the rear side grid electrodes 61 are provided substantially orthogonal to the rear side grid electrodes 61 in an in-plane direction of the rear surface of the semiconductor substrate 1, and each electrically connected to the semiconductor substrate 1 at bottom portions thereof. Note that in FIG. 1, part of the configuration of the solar battery cell is omitted.

On the light-receiving side bus electrode 52 of the solar battery cell 21, a connection tab 71 is connected along a longitudinal direction of the light-receiving side bus electrode 52. The connection tab 71 is formed from a highly electrical conductive material, for example, metal that has copper as a main component. The connection tab 71 is fixed on the light-receiving side bus electrode 52 by solder with which the tab is coated across its entire surface. Further, the dimensions (width, thickness) of the connection tab 71 are not especially restricted. These dimensions may be appropriately set in accordance with various conditions such as dimensions of the light-receiving side bus electrode 52.

One end of the connection tab 71 has a folded-back portion in the solar battery cell 11. Specifically, the one end of the connection tab 71 has a part extending from an outer edge of the solar battery cell 21 to a side of the solar battery cell 11, a part of bending in a thickness direction of the solar battery cell 21, and a part further bending in an in-plane direction of the rear surface of the solar battery cell 21 at the rear side of the solar battery cell 21. In other words, one end of the connection tab 71 on a side of the solar battery cell 11 is bent in a shape roughly like a U lying on its side on the outer edge of the solar battery cell 21. It is noted that, although the bent folded-back portion has a shape roughly like a U lying on its side in this example, the folded-back portion may have an arc shape.

On the other hand, on the rear side bus electrode 62 of the solar battery cell 11, a connection tab 72 is connected along a longitudinal direction of the rear side bus electrode 62. The connection tab 72 is formed from a highly electrical conductive material, for example, metal that has copper as a main component. The connection tab 72 is fixed on the rear side bus electrode 62 by solder with which the tab is coated across its entire surface. Further, the dimensions (width, thickness) of the connection tab 72 are not especially restricted. These dimensions may be appropriately set in accordance with various conditions, such as the dimensions of the light-receiving side bus electrode 52. Then, one end of the connection tab 72 extends from an outer edge of the solar battery cell 11 to a lower portion on the rear surface side of the solar battery cell 21.

The connection tabs 71 and 72 are connected at the rear side of the solar battery cell 21. As illustrated in FIG. 2, the connection tabs 71 and 72 are fixed by a connection portion 73 that has been formed by melting and cooling part of the solder with which the tabs are coated across their entire surfaces. Thus, the connection tabs 71 and 72 have an overlapping region at the rear side of the solar battery cell 21. Then, the connection tabs 71 and 72 are connected by the connection portion 73 that is provided in a connection region which is within this overlapping region and is narrower than the overlapping region in a longitudinal direction of the connection tab 71 (connection tab 72). In the solar battery module according to the present embodiment, by connecting the connection tabs 71 and 72 at the rear side of the solar battery cell 21 in this way, the solar battery cells 11 and 21 are electrically connected in series via the connection tabs 71 and 72.

In order to connect the connection tabs 71 and 72 on the connection portion 73 in this manner, the connection tab 71 that has been bent as illustrated in FIG. 1 and the connection tab 72 are arranged facing each other, and then only portions (or portion) of the connection tabs 71 and 72 (or any one of them) are (is) heated to melt the solder with which the surfaces of the tabs is coated. Then, the connection tabs 71 and 72 are made to abut on each other and are stuck together, so that the connection tabs 71 and 72 are connected by the connection portion 73 formed by melting and cooling a portion of the solder with which the tabs are coated over their entire surfaces. Alternatively, the connection tabs 71 and 72 may be connected by providing the connection portion 73 by welding. Note that the solar battery cells 11 and 21 are produced by a publicly-known technique.

Although for simplicity of explanation two solar battery cells 11 and 21 are shown in this example as solar battery cells constituting the solar battery module, the number of solar battery cells constituting the solar battery module is not limited to two. The solar battery module may be configured from a larger number of solar battery cells connected together.

In the solar battery module according to the present embodiment, as described above, the connection tab 71 connected to the light-receiving side bus electrode 52 of the solar battery cell 21 is bent toward the rear side of the solar battery cell 21 in a folded-back portion, and a folded back tip of the connection tab 71 is connected to the connection tab 72 connected to the rear side bus electrode 62 of the solar battery cell 11. Then, as illustrated in FIGS. 1 and 2, “α” is set shorter than “Z.” For example, in FIG. 1, play of the connection tab 71, i.e., the length of the connection tab 71 that is not connected to the connection tab 72, is “X+Y+Z−α.”

Here, “α” is a length of the connection portion 73 in the longitudinal direction of the connection tab 72 (connection tab 71) in the in-plane direction of the solar battery cell 11 (solar battery cell 21). “X” is an extended length of the connection tab 71 from the light-receiving side bus electrode 52 in the folded-back portion on the light-receiving side of the solar battery cell 21. “Y” is a length of the connection tab 71 in the thickness direction of the solar battery cell 21 in the folded-back portion. “Z” is a folded-back length of the connection tab 71 in the folded-back portion at the rear side of the solar battery cell 21.

In this way, by setting “α” to be shorter than “Z” and play of the connection tab 71 to be “X+Y+Z−α”, the play of the connection tab 71 increases, even the thermal stress possibly applied on the connection tabs 71 and 72 due to thermal expansion or thermal contraction of the solar battery module can be alleviated. For example, if an interval between the solar battery cell 11 and the solar battery cell 21 widens due to thermal contraction of the solar battery module, then a pulling stress is applied on the connection tabs 71 and 72. In short, the connection tabs 71 and 72 are subjected to stress in a pulling direction.

For this, by providing such play of the connection tab 71 as described above, this thermal stress can be alleviated by the play at the rear side of the connection tab 71, thereby preventing the connection tabs 71 and 72 from fracturing due to stress in the direction in which the connection tabs 71 and 72 are pulled. Thus, by connecting the connection tab 71 connected to the light-receiving side electrode 5 of the solar battery cell 21, to the connection tab 72 by bending the connection tab 71 toward the rear side of the solar battery cell 21, play of the connection tab 71 increases. Consequently, the stress on the connection tabs 71 and 72 produced by cyclical changes in the module temperature is alleviated, and it is possible to prevent the connection tabs 71 and 72 from breaking down due to thermal stress by use of a simple configuration. Therefore, the long-term reliability of the solar battery module is improved, and power generation costs can be reduced.

Further, according to this method, since a path through which a current flows is not excessively extended as in Patent Literature 1, a solar battery module can be obtained that suppresses deterioration in FF due to increase in the series resistances, and has high conversion efficiency.

In addition, since a rear side electrode is formed in a comb-shape, productivity is higher than for a solar battery module having a point-contact structure that is similarly provided with a rear side insulating film.

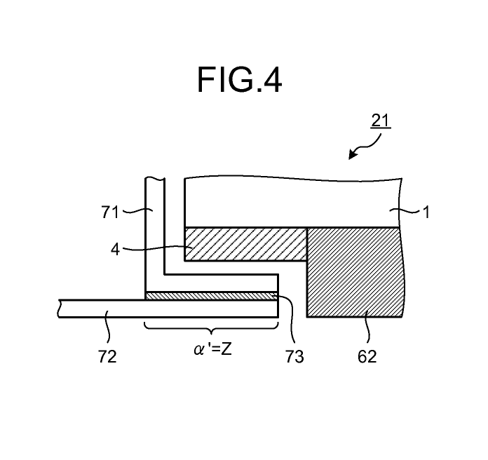

FIG. 4 is a schematic diagram illustrating the case where the connection portion 73 is provided over the entire area of the folded-back portion on the rear side of the solar battery cell 21. As illustrated in FIG. 4, if the connection portion 73 is laid across the entire area of the folded-back portion of the bent connection tab 71 in the longitudinal direction of the connection tab 72 (connection tab 71) in the in-plane direction of the solar battery cell 11 (solar battery cell 21) (Z=α′), then play of the connection tab 71 is “X+Y,” so that the stress on the connection tabs 71 and 72 caused by cyclical changes in the module temperature can not be sufficiently alleviated.

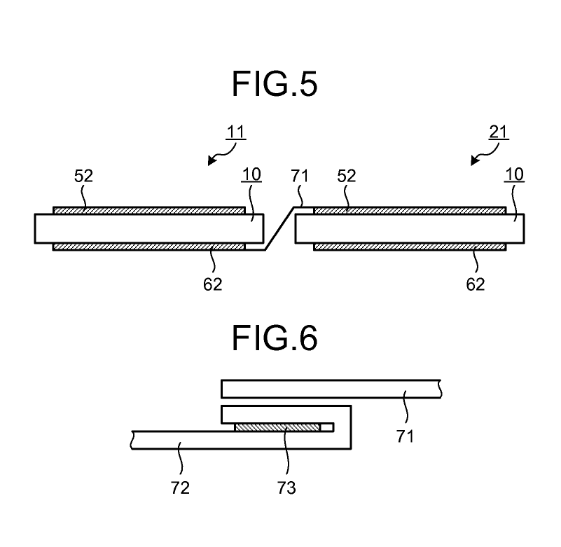

FIG. 5 is a schematic diagram illustrating a method for connecting conventional solar battery modules, in which the solar battery modules are connected with each other by a single connection tab 71. In this case, there, substantially is no play/allowance in the connection tab 71. So, if the interval between the solar battery cell 11 and the solar battery cell 21 widens due to thermal contraction in the solar battery modules, for example, a pulling stress is applied on the connection tab 71, so that stress is applied on the connection tab 71 in a direction in which the tabs are pulled. In this, the connection tab 71 fractures due to this stress.

FIG. 6 is a schematic diagram illustrating the case where the connection tabs 71 and 72 are connected by three-dimensionally bending the connection tab 72 between the solar battery cell 11 and the solar battery cell 21. In this case, a problem arises in connection between the tabs. Specifically, if trying to make connection with the connection tab 72 being bent under the condition that the connection tab 72 is coated with solder, then the bent portion of the connection tab 72 is connected with itself by the heat of the soldering process, so that the desired structure is not easily produced. When trying to produce the desired structure, it is necessary to use a method of connecting the tabs to each other by tucking a material that is unable to be soldered into the bent portion of the connection tab 72 so as not to connect the bent portion, or a method of bending the tabs after they have been connected to each other, needs to be employed. However, these methods suffer from problems with productivity as they take much time and effort, and so are not practical.

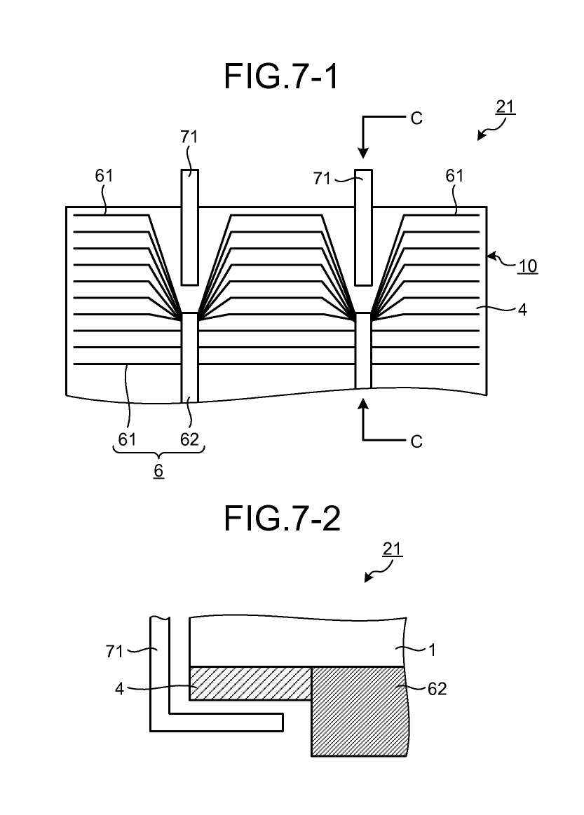

The rear surface of the solar battery cell 21 is covered with the rear side insulating film 4. Consequently, even if the connection tab 71 is bent towards the rear side of the solar battery cell 21 and connected with the connection tab 72, the solar battery cell 21 and the connection tab 71 are not connected, and insulation between the rear surface of the solar battery cell 21 and the connection tab 71 is maintained, while the play of the connection tab 71 is ensured. Supposing that the bent tip of the connection tab 71 was in contact with the rear side electrode 6, the problem with the contact can be solved by changing the pattern of the rear side electrode 6 (rear side grid electrode 61 and rear side bus electrode 62), as illustrated in FIGS. 7-1 and 7-2, thereby not resulting in a big trouble. Specifically, as illustrated in FIGS. 7-1 and 7-2, this problem can be solved by providing the pattern of the rear side electrode 6 (rear side grid electrode 61 and rear side bus electrode 62) with avoiding the arrangement region of the connection tab 71. FIG. 7-1 is a plan view of main parts illustrating an example of a pattern of the rear side electrode 6 (rear side grid electrode 61 and rear side bus electrode 62) of the solar battery module according to the present embodiment. FIG. 7-2 is a cross-sectional view of main parts illustrating an example of a pattern of the rear side electrode 6 (rear side grid electrode 61 and rear side bus electrode 62) of the solar battery module according to the present embodiment, which corresponds to a cross-section taken along a line segment C-C in FIG. 7-1.

As described above, in the solar battery module according to the present embodiment, the connection tab 71 connected to the light-receiving side electrode 5 of the solar battery cell 21 is connected to the connection tab 72 by bending the connection tab 71 toward the rear side of the solar battery cell 21. In this way, the play of the connection tab 71 increases, so that the stress on the connection tabs 71 and 72 produced by cyclical changes in the module temperature can be alleviated, and so it is possible to prevent the connection tabs 71 and 72 from fracturing due to thermal stress, by use of a simple configuration. Therefore, a solar battery module having excellent long-term reliability and low costs for power generation can be obtained as long as one relies upon the solar battery module according to the present embodiment.

It is noted that the present embodiment has the same manner as Patent Literature 3 in terms of bending a connection tab, but in Patent Literature 3, the bent portion of the tab is present between the cells, and junction between the tabs is present in a gap between the cells. In contrast, the solar battery module according to the present embodiment is very different in that it has the junction between the connection tabs 71 and 72 in the rear side of the solar battery cell 21. Thereby, the advantageous effects of the present invention achieved by this configuration can not be obtained by Patent Literature 3. Furthermore, since the connection tab 71 is bent involving the solar battery cell 21, the problem illustrated in FIG. 6, that is the tab bent portion is connected to itself when connecting the tabs together can be avoided.

Note that, although the above description is based on the assumption of a solar battery having p-n junctions formed by diffusion of an n-type dopant on the light-receiving side of the p-type semiconductor substrate 1, a solar battery having p-n junctions formed by diffusion of a p-type dopant on the light-receiving side of an n-type semiconductor substrate may also be used. The advantageous effects of the present invention can be obtained in this case too.

### INDUSTRIAL APPLICABILITY

As described above, the solar battery module according to the present invention is useful in the realization of a solar battery module having excellent long-term reliability and lower costs for power generation.

### REFERENCE SIGNS LIST

1 SEMICONDUCTOR SUBSTRATE

2 IMPURITY DIFFUSION LAYER

3 ANTI-REFLECTION FILM

4 REAR SIDE INSULATING FILM

5 LIGHT-RECEIVING SIDE ELECTRODE

6 REAR SIDE ELECTRODE

10 SEMICONDUCTOR SUBSTRATE

11 SOLAR BATTERY CELL

21 SOLAR BATTERY CELL

51 LIGHT-RECEIVING SIDE GRID ELECTRODE

52 LIGHT-RECEIVING SIDE BUS ELECTRODE

61 REAR SIDE GRID ELECTRODE

62 REAR SIDE BUS ELECTRODE

71 CONNECTION TAB

72 CONNECTION TAB

73 CONNECTION PORTION

1. A solar battery module having a first solar battery cell and a second solar battery cell, respective in-plane directions of which are substantially identical, and which are adjacent to each other in a first direction, the cells each having connection electrodes on a light-receiving side and a rear side, the first solar battery cell and the second solar battery cell being electrically connected in series by connection tabs formed from an electrically conductive material, wherein the connection tabs include:
a first connection tab that is electrically connected to the connection electrode on the rear side of the first solar battery cell and extends to the rear side of the second solar battery cell; and
a second connection tab that is electrically connected to the connection electrode on the light-receiving side of the second solar battery cell and has a folded-back portion which extends to the rear side of the second solar battery cell near the first solar battery cell from the second solar battery cell and is bent in an in-plane direction of the second solar battery cell and formed along an outer edge of the second solar battery cell,
wherein the first connection tab and the second connection tab are connected in a connection region that is within an overlapping region in which the first connection tab and the second connection tab overlap in a rear side of the second solar battery cell, and that is narrower than the overlapping region in the first direction.

2. The solar battery module according to claim 1, wherein the second solar battery cell includes a passivation film on a rear side.

3. The solar battery module according to claim 1, wherein the connection electrode on the rear side of the second solar battery cell is a comb electrode having a comb shape.

4. The solar battery module according to claim 3, wherein the comb electrode is provided in a region that excludes an arrangement region of the second connection tab that is bent up to the rear side of the second solar battery cell.

5. The solar battery module according to claim 1, wherein the folded-back portion has an arc shape in a thickness direction of the second solar battery cell.
